(19) United States
(12) Patent Application Publication
(10) Pub. No.: US 2026/0047035 A1
(43) Pub. Date: Feb. 12, 2026

(54) METHODS AND APPARATUS FOR COLD PLATE DESIGN

(71) Applicant: Cisco Technology, Inc., San Jose, CA (US)

(72) Inventors: Chejung Liu, San Jose, CA (US); Vic Hong Chia, Sunnyvale, CA (US); Kuan-Chieh Chen, Granite Bay, CA (US)

(21) Appl. No.: 18/796,521

(22) Filed: Aug. 7, 2024

(51) Int. Cl. H05K 7/20; G06F 1/20

(52) U.S. Cl. CPC H05K 7/20254; G06F 1/20; H05K 7/20263

(57) ABSTRACT

In one embodiment, an apparatus includes a first plate having a first plurality of fins integrally formed thereon and a second plate having a second plurality of fins integrally formed therein. The first plurality of fins is arranged to have a first fin density, and the second plurality of fins is arranged to have a second fin density. When the first plate and the second plate are assembled together, the first plurality of fins and the second plurality of fins are interleaved to form a first fin array, the first fin array having a third fin density.

### TECHNICAL FIELD

The present disclosure relates generally to thermal systems suitable for use in cooling computing systems. More particularly, the present disclosure relates to providing a liquid cooling system that includes a cold plate with enhanced cooling capabilities.

### BACKGROUND

As the capabilities of computing systems such as computer processing units (CPUs), graphical processing units (GPUs), and application-specific integrated circuits (ASICs) continues to improve, the ability to effectively cool computing systems is becoming increasingly critical. Liquid cooling systems which include cold plates are often used to cool computing systems. Cold plates that are part of liquid cooling systems may include fins that are arranged to provide areas for heat dissipation within the cold plates.

While cold plates with fins may be effective in providing some cooling to computing systems, the manufacturing processes that enable uniform fins to be provided in cold plates is often inefficient due to cost, lead-time, and physical limitations of the manufacturing processes. As such, the cold plates used in liquid cooling systems may not be capable of providing the amount of cooling needed for improved computing systems.

### BRIEF DESCRIPTION OF THE FIGURES

FIG. 1 is a block diagram representation of a heat source being cooled by a cold plate in accordance with an embodiment.

FIG. 2 is a diagrammatic side view representation of a cold plate, e.g., cold plate 104 of FIG. 1, in accordance with an embodiment.

FIG. 3 is a process flow diagram which illustrates a general method of creating a cold plate that may be used in a liquid cooling solution assembly in accordance with an embodiment.

FIG. 4 is a process flow diagram which illustrates a method of creating a cold plate that includes applying a blazing material to bond fin features to a bottom plate of the cold plate in accordance with an embodiment.

FIG. 5A is a diagrammatic side view representation of a cold plate that includes an area or zone which is configured to dissipate more heat than other areas on the cold plate in accordance with an embodiment.

FIG. 5B is a diagrammatic top view representation of a cold plate that includes an area or zone configured to dissipate more heat than other areas on the cold plate, e.g., area 524 of cold plate 504 of FIG. 5A, in accordance with an embodiment.

FIG. 6 is a diagrammatic side view representation of a cold plate in which selected fins of a top plate are bonded to a bottom plate to provide an area of substantially increased heat dissipation in accordance with an embodiment.

FIG. 7 is a diagrammatic side view representation of a cold plate in which a bottom plate includes fins configured to provide an area of substantially increased heat dissipation in accordance with an embodiment.

FIG. 8 is a diagrammatic side view representation of a cold plate in which a top plate includes fins configured to provide an area of substantially increased heat dissipation in accordance with an embodiment.

FIG. 9A is a diagrammatic representation of a top plate with a first pattern of fins and a bottom plate with a second pattern of fins which are arranged to be assembled to form a cold plate with an area of increased heat dissipation in accordance with an embodiment.

FIG. 9B is a diagrammatic representation of a first pattern of fins associated with a top plate and a second pattern of fins associated with a bottom plate, e.g., first pattern of fins 920a and second pattern of fins 920b, that cooperate to define an area of increased heat dissipation in accordance with an embodiment.

FIG. 10A is a diagrammatic representation of a top plate with a first pattern of fins and a bottom plate with a second pattern of fins which are arranged to be assembled to form a cold plate reduce flow impedance of liquid within the cold plate in accordance with an embodiment.

FIG. 10B is a diagrammatic representation of a first pattern of fins associated with a top plate and a second pattern of fins associated with a bottom plate, e.g., first pattern of fins 1020a and second pattern of fins 1020b, that cooperate to define areas of increased flow impedance in accordance with an embodiment.

FIG. 11 is a process flow diagram which illustrates a method of creating a cold plate that includes selecting top and bottom plates to meet design parameters in accordance with an embodiment.

FIG. 12 is a diagrammatic representation of an overall process of providing a cold plate that may be used to cool a heat source in accordance with an embodiment.

### DESCRIPTION OF EXAMPLE EMBODIMENTS

### Overview

In one embodiment, an apparatus includes a first plate having a first plurality of fins integrally formed thereon and a second plate having a second plurality of fins integrally formed therein. The first plurality of fins is arranged to have a first fin density, and the second plurality of fins is arranged to have a second fin density. When the first plate and the second plate are assembled together, the first plurality of fins and the second plurality of fins are interleaved to form a first fin array, the first fin array having a third fin density. The second plate may include a surface such that when the first plate and the second plate are assembled together, the first plurality of fins is bonded to the surface.

Further understanding of the features and advantages of the embodiments described herein may be realized by reference to the remaining portions of the specification and the attached drawings.

### EXAMPLE EMBODIMENTS

The following description is presented to enable one of ordinary skill in the art to make and use the embodiments. Descriptions of specific embodiments and applications are provided only as examples, and various modifications will be readily apparent to those skilled in the art. The general principles described herein may be applied to other applications without departing from the scope of the embodiments. Thus, the embodiments are not to be limited to those shown, but are to be accorded the widest scope consistent with the principles and features described herein. For purposes of clarity, details relating to technical material that is known in the technical fields related to the embodiments have not been described in detail.

Liquid cooling systems often include cold plates that are used to dissipate heat from a heat source, e.g., a computing system. Generally, a cold plate is positioned close to, as for example over or next to, a heat source such that heat emanating from the heat source is essentially absorbed by the cold plate. A cold plate is assembled from a top plate and a bottom plate, and liquid provided to the cold plate flows through the cold plate to carry heat away from the cold plate.

A cold plate that is incorporated in a liquid cooling system may include fins or fin-like structures that are arranged to provide extra surface area that facilitates the dissipation of heat via a liquid flowing through the cold plate. Cold plates with are generally effectively provide some cooling capabilities, manufacturing processes that enable uniform fins to be provided in cold plates is often inefficient due to cost, lead-time, and physical limitations of the manufacturing processes. As such, the cold plates used in liquid cooling systems may not be capable of providing the amount of cooling needed for computing systems as computing systems continue to become more powerful and, hence, generate more heat.

To improve the heat absorption or cooling properties of a liquid cooling system that incorporates a cold plate, fins included a first plate of the cold plate may be bonded to a surface of a second plate of the cold plate. For example, fins formed on a top plate of a cold plate may be bonded to a surface of a bottom plate of the cold plate using, but not limited to using, a diffusion bonding method, a blazing method, and/or a friction bonding method. By bonding fins formed on a first plate to a surface of a second plate, the conductivity of heat through a cold plate may be improved.

Heat absorption and cooling properties of a liquid cooling system may also be improved by increasing and/or varying the density of fins included in a cold plate. Fins created on a top plate and fins created on a bottom plate may have substantially the same fin thickness and spacing. In one embodiment, when a top plate with fins and a bottom plate with fins that have the same thickness and spacing are assembled together, the resulting array of fins may have an increased fin density of approximately fifty percent over a cold plate which includes substantially only one plate that includes fins. In another embodiment, a cold plate may have different fin densities such that a particular area of the cold plate may be targeted to provide an increased amount of heat absorption, while other areas of the cold plate may provide a lower amount of heat absorption.

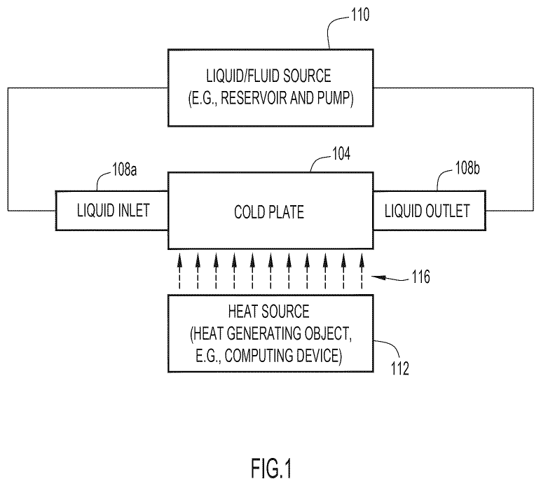

FIG. 1 is a block diagram representation of a heat source being cooled by a cold plate in accordance with an embodiment. A heat source 112, which may be any heat generating object, may be positioned in the vicinity of a cold plate 104 that is part of a liquid cooling arrangement or system configured to cool heat source 112. Heat source 112 may be, for example, a computing device such as a computer processing unit (CPU), a graphical processing unit (GPU), and/or an application-specific integrated circuit (ASIC). Heat source 112 may also generally be a network device. Heat source 112 generates heat 116, i.e., heat 116 emanates from heat source 112.

A cooling liquid is provided to cold plate 104 by a fluid or liquid source 110. As cold plate 104 absorbs heat 116, the liquid provided to cold plate 104 by liquid source 110 may be heated or otherwise warned. Liquid source 110 may generally include a reservoir and a pump which cooperate to provide liquid to cold plate 104 using a liquid inlet 108a and to carry liquid away from cold plate 104 through a liquid outlet 108b. That is, liquid inlet 108a provides liquid or fluid to cold plate 104, and liquid outlet 108b carries heated liquid away from cold plate 104.

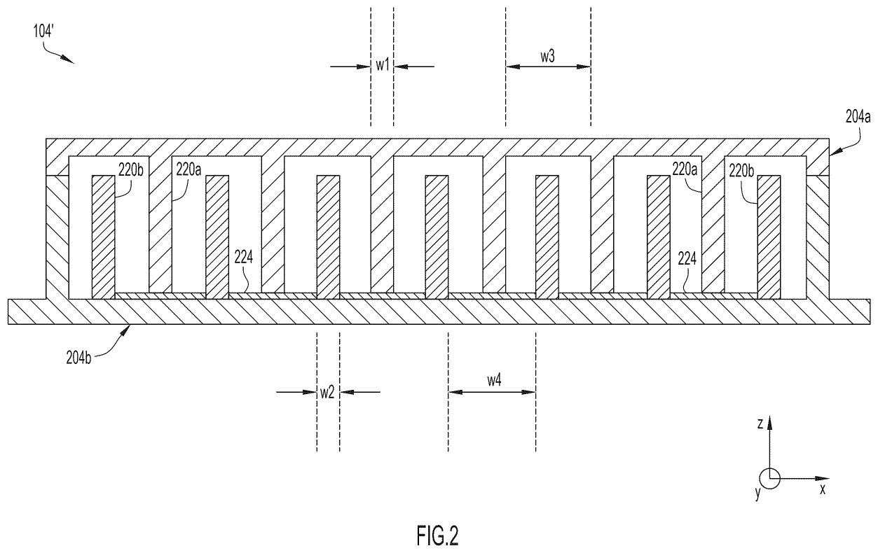

Cold plate 104 may be formed from a top plate and a bottom plate that each include fins. Fins, which may be plate fins or pin fins, are arranged to provide additional surface area for heat dissipation within cold plate 104. Cold plate 104 may generally be formed from a conductive material such as metal, e.g., copper or aluminum. With respect to FIG. 2, one configuration of cold plate 104 that is formed from a top plate and a bottom plate will be described in accordance with an embodiment. Cold plate 104′ includes a top plate 204a and a bottom plate 204b which are arranged to be assembled or otherwise coupled together.

Top plate 204a includes fin features or fins 220a, and bottom plate 204b includes fin features or fins 220b. Fins 220a may be integrally formed with top plate 204a, and fins 220b may be integrally formed with bottom plate 204b using any suitable process. Suitable processes may include, but are not limited to including, skiving, die-casting, injection-molding, three-dimensional (3D) printing, and computer numerical control (CNC).

As shown, fins 220a are interleaved with fins 220b such that at least some fins 220a are effectively disposed between adjacent fins 220b, and at least some fins 220b are effectively disposed between adjacent fins 220a. Fins 220a may have a fin thickness or width w1, and adjacent fins 220a may be spaced apart by a gap width w3. Fins 220b may have a fin thickness or width w2 and adjacent fins 220b may be spaced apart by a gap width w4. Widths w1-w4 may vary widely. As will be appreciated by those skilled in the art, widths w1-w4 may be determined based on the capabilities of a manufacturing process used to create fins 220a, 220b. In one embodiment, widths w1, w2 may be approximately 0.1 millimeters (mm), and widths w3, w4 may be in a range between approximately 0.2 mm and approximately 0.3 mm.

In one embodiment, fins 220a may be bonded to a surface of bottom plate 204b. Bonding may be accomplished using any suitable method. By way of example, fins 220a may be bonded to a surface of bottom plate using a bonding agent 224 and a diffusion bonding process, a blazing process, and/or a friction bonding process. Bonding fins 220a to a surface of a bottom plate facilitates the heat dissipation properties of cold plate 104′.

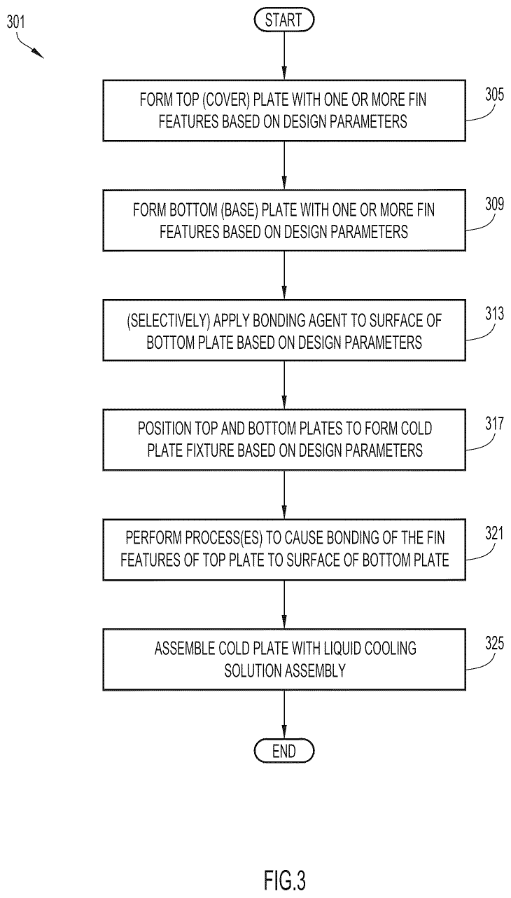

Referring next to FIG. 3, a general method of creating a cold plate that may be used in as a part of a liquid cooling arrangement will be described in accordance with an embodiment. A method 301 of creating a cold plate begins at a step 305 in which a top, or cover plate, is formed with one or more fin features based on design parameters. As mentioned above, fin features may be formed using methods including, but not limited to including skiving, die-casting, 3D printing, and CNC. The design parameters may generally specify a number of fin features, at least one density associated with fin features, and an overall size of top and bottom plates.

In a step 309, a bottom, or base, plate may be formed with one or more fin features based on design parameters. Once the bottom plate is formed, a bonding agent may be selectively applied to a surface of the bottom plate in a step 313. The amount of bonding agents to apply, as well as locations at which to apply the bonding agent, may vary based on design parameters. The bonding agent may generally be any suitable material that promotes the bonding of the fins of a top plate to a surface of a bottom plate.

After the bonding agent is applied to the surface of the bottom plate, process flow moves to a step 317 in which the top plate and the bottom plate are positioned or otherwise aligned such that a cold plate fixture may be formed based on design parameters. Such positioning may generally involve fin features of the top plate contacting or abutting a surface of the bottom plate on which a bonding agent has been applied.

At least one process may be performed to cause the fin features of the top plate to bond with the surface of the bottom plate in a step 321. For example, heat may be applied to the top plate and/or bottom plate to cause the bonding agent to bond fin features of the top plate to the bottom plate.

Once the fin features of the top plate are bonded to the surface of the bottom plate, the cold plate may be assembled with a liquid cooling solution arrangement or assembly in a step 325. In other words, the cold plate may be integrated into a liquid cooling system that is arranged to provide cooling to a heat source. Upon assembling the cold plate into the liquid cooling system, the method of creating a cold plate is completed.

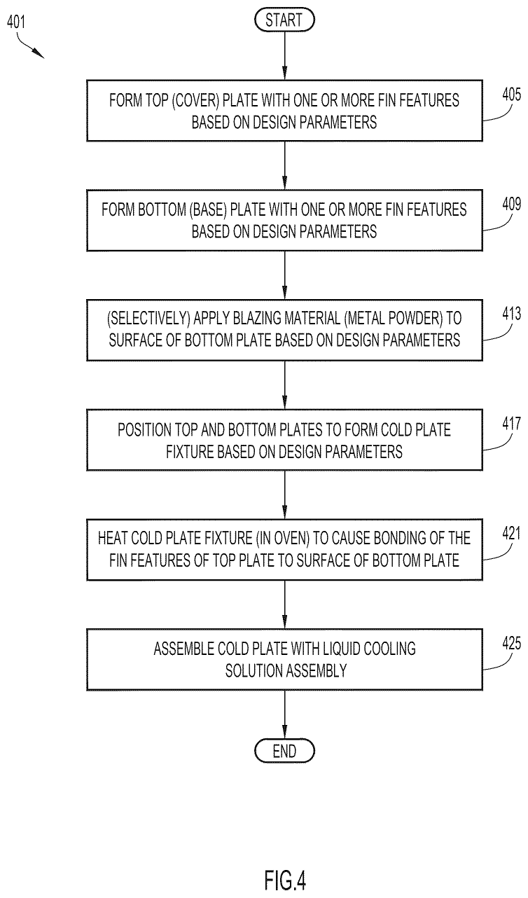

In one embodiment, forming a cold plate may include diffusion bonding. By way of example, diffusion bonding or welding may be used to cause fin features of a top plate to bond to a surface of a bottom plate. FIG. 4 is a process flow diagram which illustrates a method of creating a cold plate that includes utilizing diffusion bonding to bond fin features of a top plate to a bottom plate of the cold plate in accordance with an embodiment. A method 401 of creating a cold plate begins at a step 405 in which a top is formed with one or more fin features based on design parameters.

In a step 409, a bottom plate may be formed with one or more fin features based on design parameters. After the top and bottom plates are formed, a blazing material may be selectively applied to a surface of the bottom plate in a step 413. The blazing material may be a metal powder, e.g., a copper powder.

Once the blazing material is applied to the surface of the bottom plate, the top plate and the bottom plate are positioned such that a cold plate fixture may be formed in a step 417. In a step 421, the cold plate fixture is heated, e.g., in an oven, to cause the fin features of the top plate to bond to a surface of the bottom plate. The cold plate may be assembled with a liquid cooling solution arrangement or assembly in a step 425 after the fins features of the top place are bonded to the surface of the bottom plate, and the method of creating a cold plate is completed.

A cold plate may generally be formed uniformly. That is, a cold plate may be formed from a top plate and a bottom plate that each have approximately the same density of fins or fin features. However, a cold plate is not limited to being formed uniformly. By way of example, a cold plate may be configured to have the capacity to provide more heat dissipation in a particular area than in other areas. That is, a local density of fins may be increased in a particular to address a cooling expectation or requirement. Such a configuration for a cold plate may allow a liquid cooling system to operate more efficiently, as the cold plate may effectively provide more cooling to a heat source in particular areas.

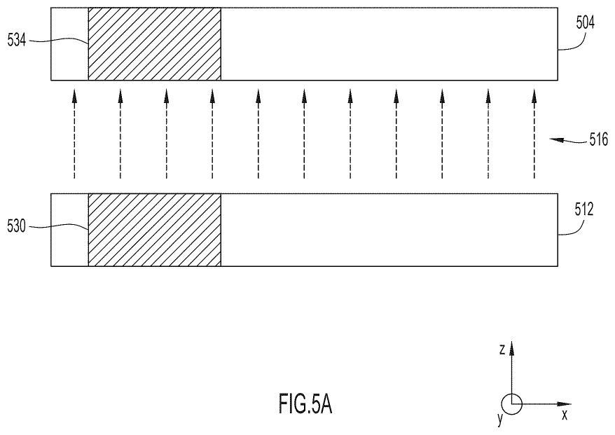

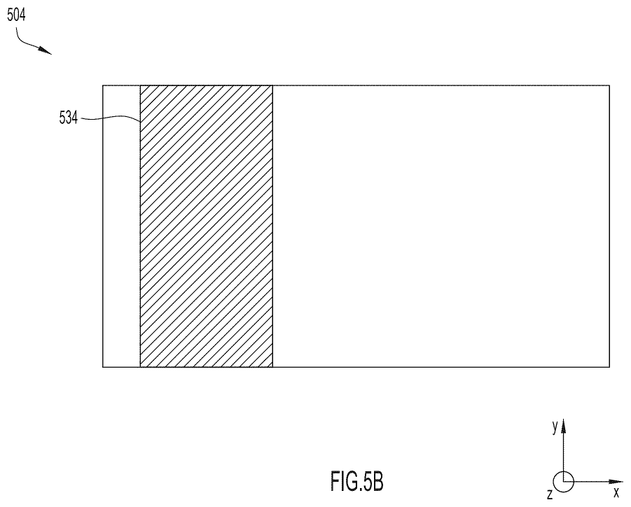

A heat source may have an area or zone which generates more heat than generated by other areas or zones of the heat source. That is, a heat source may have a “hot spot.” A cold plate may be configured to provide more cooling capabilities, or to dissipate more heat, to cool the hot spot than provided to cool other areas of the heat source. FIG. 5A is a diagrammatic side view representation of a cold plate that includes an area or zone which is configured to dissipate more heat than other areas on the cold plate, and FIG. 5B is a diagrammatic top view representation of the cold plate in accordance with an embodiment. A cold plate 504 is positioned over a heat source 512. Heat source 512 includes an area 530 which generates a larger amount of heat 516 than generated by other areas or heat source 512.

Cold plate 504 generally enables heat 516 to be absorbed and may be configured to have an area of increased heat absorption 534 which provides additional cooling capabilities. The additional cooling capabilities may be provided in a variety of different ways. For example, area of increased heat absorption 534 may include fins of a top plate that are bonded to a surface of a bottom plate, while other areas of cold plate 504 may have fins of the top plate that are not bonded to the surface of the bottom plate. Alternatively, area of increased heat absorption 534 may have more fins, or a higher fin density, than other areas of cold plate 504.

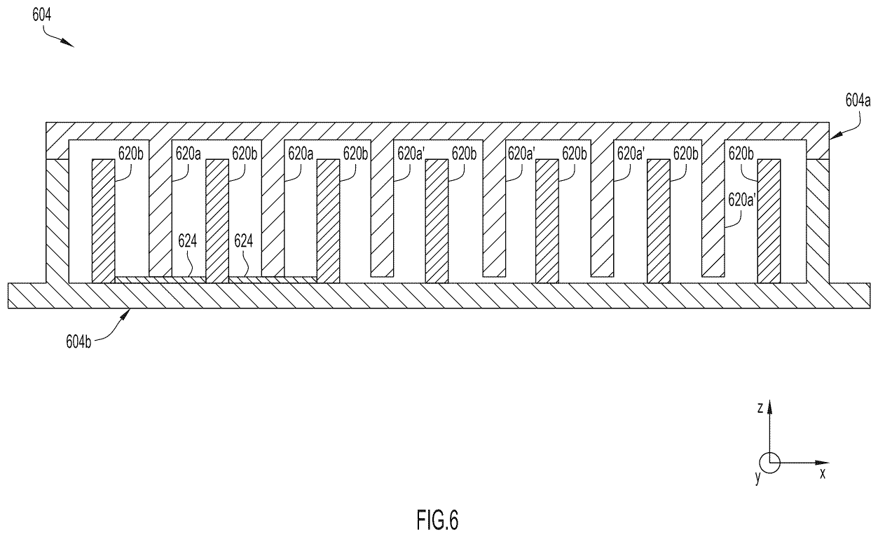

As previously mentioned, creating a cold plate that includes fins of a top plate that are bonded to a surface of a bottom plate increases heat absorption capabilities of the cold plate. Therefore, a cold plate that substantially only bonds fins of a top plate to a surface of a bottom plate in one or more particular areas or zone of the cold plate has increased heat absorption capabilities in the particular areas or zones. FIG. 6 is a diagrammatic side view representation of a cold plate in which selected fins of a top plate are bonded to a bottom plate to provide an area of substantially increased heat dissipation in accordance with an embodiment. A cold plate 604 includes a top plate 604a and a bottom plate 604b. Top plate 604a includes fins 620a, 620a′, and bottom plate 604b includes fins 620b.

Fins 620a are bonded to a surface of bottom plate 604b with a bonding agent 624. In one embodiment, bonding agent 624 may be a blazing material that enables diffusion bonds to be formed between fins 620a and the surface of bottom plate 604b. Fins 620a′ are not bonded to the surface of bottom plate 604b. As such, the conductivity of fins 620a is greater than that of fins 620a′, and fins 620a may dissipate more heat than fins 620a′.

A cold plate that includes a particular area or zone with substantially higher cooling capabilities may be arranged to include a higher density of fins in the particular area. In one embodiment, a bottom plate of a cold plate may include more fins in the particular area than in other areas of the cold plate. The increased density of fins enables more heat dissipation to be achieved in the particular area than in other areas of the cold plate. FIG. 7 is a diagrammatic side view representation of a cold plate in which a bottom plate includes fins configured to provide an area of substantially increased heat dissipation in accordance with an embodiment. A cold plate 704 includes a top plate 704a and a bottom plate 704b. Top plate 704a includes fins 720a, 720a′, and bottom plate 704b includes fins 720b. Fins 720a, 720a′ are bonded to a surface of bottom plate 704b with a bonding agent 724.

While fins 720a, 720a′ have a substantially uniform density, the density of fins 720b is not of a substantially uniform density. As shown, bottom plate 704b includes areas without any fins. Fins 720b cooperate with fins 720a to create an area with an overall higher fin density than an area that includes fins 720a′ but effectively no corresponding fins associated with bottom plate 704b. As the fin density created by fins 720a, 720b is greater than the fin density associated with fins 720a′, the area defined to include fins 720a, 720b may provide more heat absorption ability than provided in other areas.

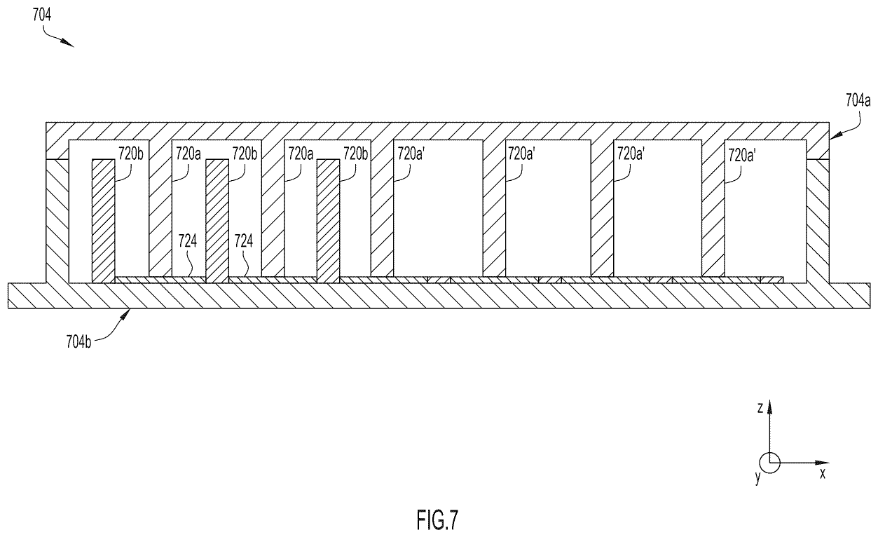

Rather than increasing the fin density in one or more areas of a cold plate to increase heat absorption capabilities by modifying a bottom plate, a top plate may be modified instead. FIG. 8 is a diagrammatic side view representation of a cold plate in which a top plate includes fins configured to provide an area of substantially increased heat dissipation in accordance with an embodiment. A cold plate 804 includes a top plate 804a and a bottom plate 804b. Top plate 804a includes fins 820a and bottom plate 804b includes fins 820b, 820b′. Fins 820a are bonded to a surface of bottom plate 804b with a bonding agent 824.

Fins 820b, 820b′ have a substantially uniform density, as shown. The density of fins 820a is not substantially uniform, and top plate 804a includes areas that do not include fins. Fins 820a cooperate with fins 820b to create an area with an overall higher fin density than an area that includes fins 820b′. As the fin density created by fins 820a, 820b is greater than the fin density associated with fins 820b′, the area defined to include fins 820a, 820b may provide more heat absorption ability than provided in other areas.

The configuration of top plates and bottom plates used in a cold plate may vary. In some embodiments, top and bottom plates may have substantially the same orientation or layout of fins. In other embodiments, top and bottom plates may have different orientations or pattern of fins. By selecting different pairings of top and bottom plates, the densities of fins included in a cold plate may be readily adjusted. As a result, different top plates and/or bottom plates may be interchanged to efficiently created cold plates with different characteristics. The ability to adjust the densities of patterns of fins when assembling a cold plate allows specific characteristics of heat sources to be addressed. For example, as previously mentioned, when a heat source has a particular hot spot, a cold plate may be configured to effectively provide extra cooling in an area that cools the hot spot, or allows heat generated by the hot spot to be dissipated.

By interchanging different top plates and/or bottom plates, various combinations of fin densities and patterns may be achieved. As a result, the efficiency with which cold plates may be customized or tailored for specific uses may be increased. The density of fins that effectively form a fin array may be increased in specific areas to correspond with the location or hotspot of the heat source. Providing targeted cooling using areas or zones of a cold plate to address hot spots allows for efficient thermal management.

When a top plate and a bottom plate have approximately the same fin pattern and, hence, approximately the same fin density, pairing the top plate and the bottom plate to form a cold plate effectively doubles the density of the fins with respect to the cold plate. Pairing a top plate and a bottom plate that have different fin patterns and/or densities enables a cold plate to be configured to address various purposes. For example, pairing a top plate and a bottom plate that have different configurations may enable a cold plate to address a particular cooling expectation by increasing the density of fins in a particular area, and may enable a flow impedance of liquid flowing through the cold plate to be reduced.

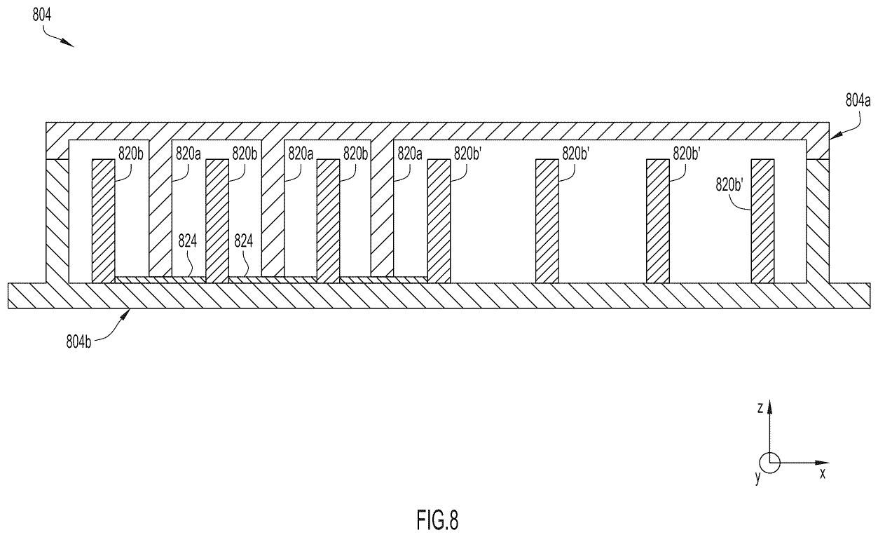

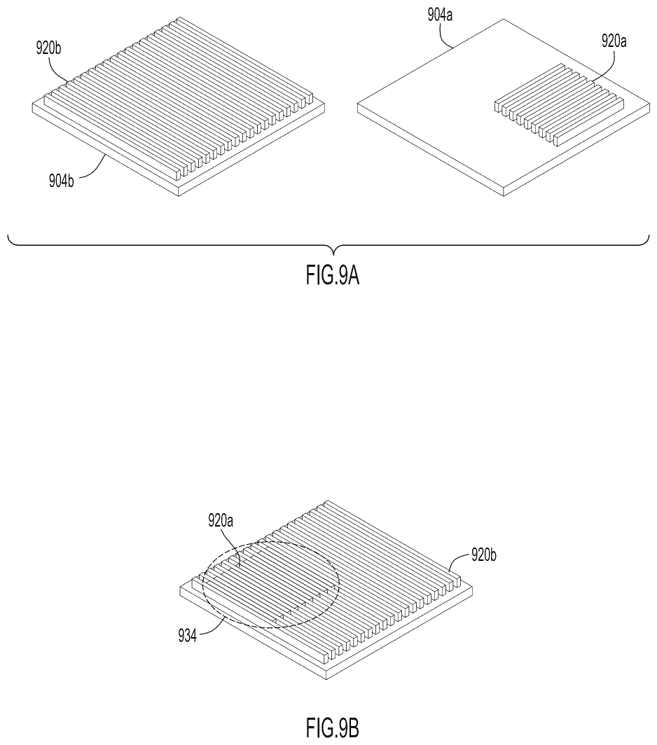

FIG. 9A is a diagrammatic representation of a top plate with a first pattern of fins and a bottom plate with a second pattern of fins which are arranged to be assembled to form a cold plate with an area of increased heat dissipation in accordance with an embodiment. A top plate 904a includes a first pattern of fins 920a and a bottom plate 904b includes a second pattern of fins 920b. First pattern of fins 920a covers a relatively small portion of a surface of top plate 904a, while second pattern of fins 920b covers a relatively large portion of a surface of bottom plate 904b.

When top plate 904a and bottom plate 904b are assembled together to form a cold plate, fins included in first pattern of fins 920a and fins included in second pattern of fins 920b effectively interleave to form an area of increased heat absorption. Referring next to FIG. 9B, the formation of an area of increased heat absorption 934 that is achieved by first pattern of fins 920a and second pattern of fins 920b will be described in accordance with an embodiment. Fins of first pattern of fins 920a and fins of second pattern of fins 920b cooperate to effectively form a fin array and to provide increased heat absorption, or increased cooling capabilities.

While patterns of fins form on top and/or bottom plates of a heat plate may cooperate to enable an area of increased heat absorption to be substantially defined, patterns of fins on top and bottom plates may additionally, or alternatively, cooperate to essentially define areas which enable flow impedance of liquid to be reduced. In one embodiment, approximately a total area of fins provided on top and bottom plates of a cold plate may include an arrangement of different fin patterns such that flow impedance may be reduced. By providing a relatively lower flow impedance and a relatively increased fin density, power efficiency associated with a pump that provides liquid flow through a cold plate may be improved.

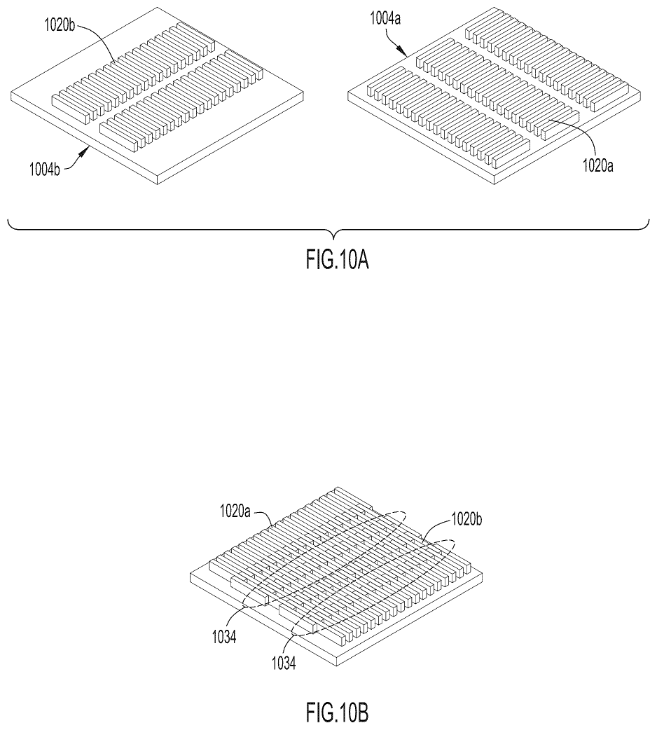

FIG. 10A is a diagrammatic representation of a top plate with a first pattern of fins and a bottom plate with a second pattern of fins which are arranged to be assembled to form a cold plate reduce flow impedance of liquid within the cold plate in accordance with an embodiment. A top plate 1004a includes first patterns of fins 1020a and a bottom plate 1004b includes second patterns of fins 1020b. First patterns of fins 1020a and second patterns of fins 1020b are arranged to be interleaved when a cold plate is assembled using top plate 1004a and bottom plate 1004b, as shown in FIG. 10B. As shown, first patterns of fins 1020a and second patterns of fins 1020b cooperate to define areas of increased flow impedance 1034 in accordance with an embodiment.

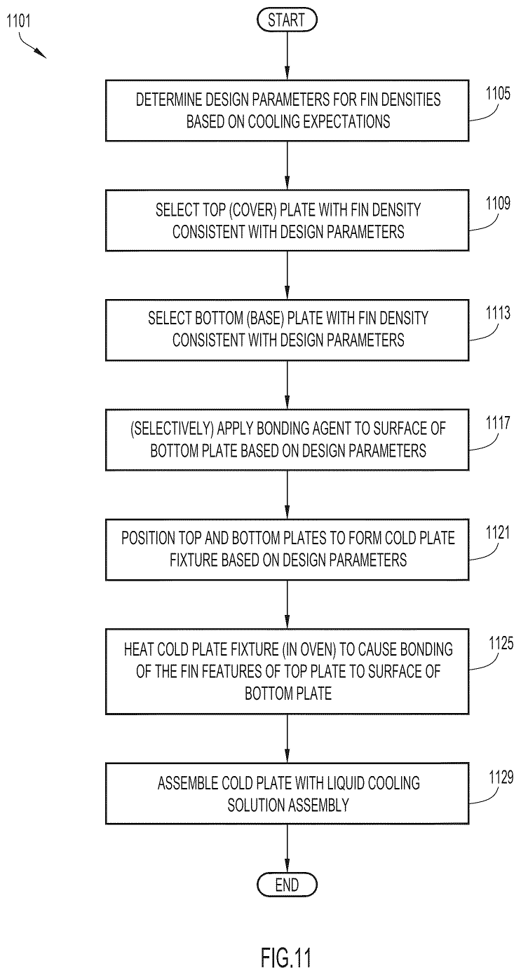

As previously mentioned, a cold plate may be assembled or otherwise created by selecting top and bottom plates which may provide the cold plate with desired characteristics, e.g., an area that may be arranged to provide increased heat absorption. With reference to FIG. 11, a method of creating a cold plate that includes selecting top and bottom plates to meet design parameters will be described in accordance with an embodiment. A method 1101 of creating a cold plate begins at a step 1105 in which design parameters for fin densities of the cold plate are determined or otherwise identified, as for example based on cooling expectations. For example, if a heat source that is to be cooled using the cold plate includes a hot spot or other area of increased heat, fin densities may be selected such that a fin density of fins that may be positioned to address the hot spot may be higher than a fin density of fins at other areas of the cold plate.

In a step 1109, a top or cover plate of the cold plate may be selected. The selected top plate may generally have a fin density, and fin pattern, that is consistent with the design parameters. A bottom or base plate of the cold plate may then be selected in a step 1113 based on a fin density, and fin pattern, that is consistent with the design parameters.

Once top and bottom plates are selected, process flow proceeds to a step 1117 in which a bonding agent is selectively applied to a surface of the bottom plate based on design parameters. The bonding agent may be applied in areas where fin features of a top plate may come into contact with the surface of the bottom plate.

The top and bottom plates are positioned or aligned to from a cold plate fixture based on design parameters in a step 1121. Then, in a step 1125, the cold plate fixture may be heated, as for example in an oven, to cause bonding of fin features of the top plate to the surface of the bottom plate. After the fin features of the top plate are bonded to the surface of the bottom plate, the cold plate is effectively completed and may then be assembled with a liquid cooling solution assembly in a step 1129. The method of creating a cold plate is completed upon assembling the cold plate with a liquid cooling solution assembly.

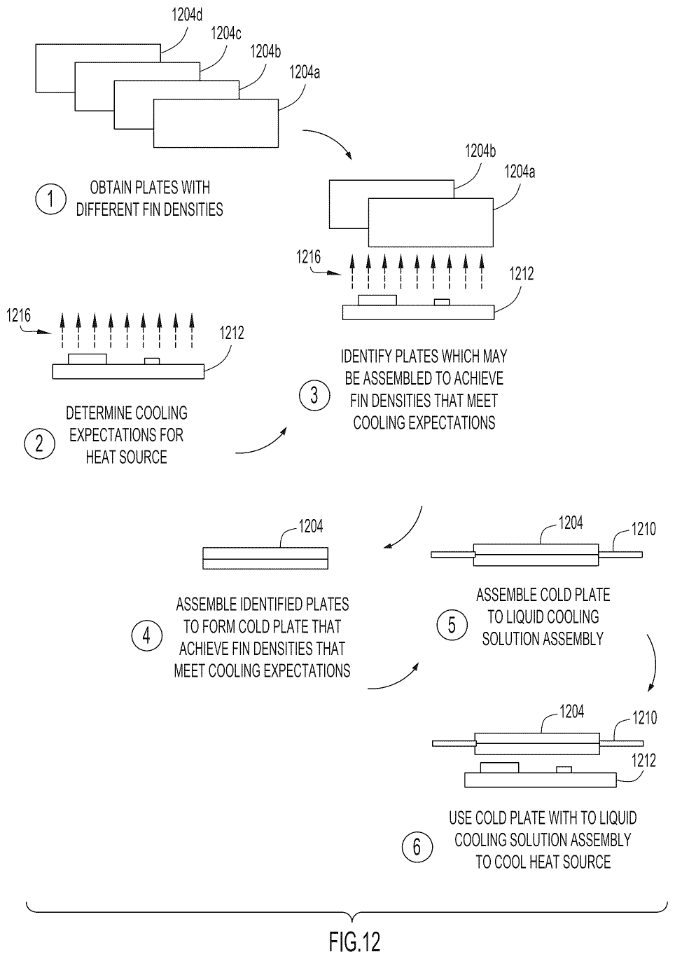

FIG. 12 is a diagrammatic representation of an overall process of providing a cold plate that may be used to cool a heat source in accordance with an embodiment. At a time t1, access to plates 1204a, 1204b, 1204c, and 1204d is obtained. Plates 1204a-d, in one embodiment, may have different densities and/or patterns of fins, and may each be used as either a top plate or a bottom plate of a cold plate. In general, plates 1204a-d may each be arranged to be paired to every other plate 1204a-d. That is, each plate 1204a-d may be arranged to interface with every other plate 1204a-d to create fin arrays of different fin densities.

At a time t2, cooling expectations for a heat source 1212 may be determined. By way of example, heat source 1212 may be a computing system which may emanate heat 1216 such that amounts of heat being emanated may differ across a surface of heat source 1212. In other words, a heat generating profile of heat source 1212 may not be uniform and may, instead, be such that different areas or zones of heat source 1212 may generate different amounts of heat 1216. As such, determining cooling expectation may include determining how much heat dissipation or heat absorption capabilities may be desired based on a heat generating profile of heat source 1212.

At a time t3, plates 1204a, 1204b which may be assembled to achieve fin densities and/or patterns that meet or exceed cooling expectations are identified. After plates 1204a, 1204b are identified, plates 1204a, 1204b are assembled to form a cold plate 1204 that achieve fin densities and/or patterns that meet cooling expectations at a time t4. For example, fins having a first fin density on plate 1204a may cooperate with fins having a second fin density on plate 1204b to create an overall fin array having a third fin density when plates 1204a, 1204b are assembled together to form cold plate 1204.

Once cold plate 1204 is formed, as for example using any suitable process such as diffusion bonding, cold plate 1204 is assembled to a liquid cooling solution assembly 1210 at a time t5. Liquid cooling solution assembly 1210 provides liquid or fluid to cold plate 1204 that enables heat to be carried away from cold plate 1204. Together, liquid cooling solution assembly 1210 and cold plate 1204 may effectively form a liquid cooling system.

At a time t6, cold plate 1204 and liquid cooling solution assembly 1210 are used to cool heat source 1212. To enable cold plate 1204 to cool heat source 1212, cold plate 1204 may be placed in relatively close proximity to, such as at a predetermined distance from, heat source 1212. For example, cold plate 1204 may be placed next to, or over, heat source 1212.

As described above, fins or fin features of a top plate of a cold plate may be bonded, as for example through diffusion bonding, to a surface of a bottom plate of the cold plate. It should be appreciated that lieu of, or in addition, to fins of a top plate being bonded to a surface of a bottom plate, fins of a bottom plate may be bonded to a surface of a top plate without departing from the spirit or the scope of the disclosure.

In some aspects, the techniques described herein relate to an apparatus including: a first plate, the first plate including a first plurality of fins integrally formed thereon, the first plurality of fins being arranged to have a first fin density; and a second plate, the second plate including a second plurality of fins integrally formed thereon, the second plurality of fins being arranged to have a second fin density, wherein when the first plate and the second plate are assembled together, the first plurality of fins and the second plurality of fins are interleaved to form a first fin array, the first fin array having a third fin density.

In some aspects, the techniques described herein relate to an apparatus wherein the first plate further includes a third plurality of fins integrally formed thereon, the third plurality of fins having the first fin density, wherein when the first plate and the second plate are assembled together, the third plurality of fins forms a second fin array, the second fin array having the first fin density.

In some aspects, the techniques described herein relate to an apparatus wherein the first plate further includes a third plurality of fins integrally formed thereon and the second plate further includes a fourth plurality of fins formed thereon, the third plurality of fins having the first fin density, the fourth plurality of fins having a fourth fin density, wherein when the first plate and the second plate are assembled together, the third plurality of fins and the fourth plurality of fins form a second fin array, the second fin array having a fifth fin density.

In some aspects, the techniques described herein relate to an apparatus wherein the second plate includes a surface, and wherein when the first plate and the second plate are assembled together, the first plurality of fins is bonded to the surface.

In some aspects, the techniques described herein relate to an apparatus wherein the first plate is formed from a metal and the second plate is formed from the metal, and wherein the first plurality of fins is bonded to the surface using one selected from a group including diffusion bonding, blazing, and friction bonding.

In some aspects, the techniques described herein relate to an apparatus wherein when the first plate and the second plate are assembled together, the first plate and the second plate form a cold plate, the apparatus further including: a liquid cooling solution arrangement, the liquid cooling solution arrangement including an inlet and an outlet, the inlet being arranged to provide a liquid to the cold plate, the outlet being arranged to carry the liquid away from the cold plate.

In some aspects, the techniques described herein relate to a system including: a heat source; and a liquid cooling arrangement, the liquid cooling arrangement including a cold plate, a liquid source, a liquid inlet, and a liquid outlet, the liquid cooling arrangement arranged to cool the heat source, wherein the cold plate includes a first plate including a first plurality of fins having a first fin density and a second plate including a second plurality of fins having a second fin density, the first plurality of fins being interleaved with the second plurality of fins to form a first fin array having a third fin density, and wherein the liquid source provides a liquid through the liquid inlet to the cold plate and the liquid outlet carries the liquid away from the cold plate.

In some aspects, the techniques described herein relate to a system wherein the second plate includes a surface, and wherein the first plurality of fins is bonded to the surface.

In some aspects, the techniques described herein relate to a system wherein the first plate further includes a third plurality of fins having the first fin density, and the heat source includes a first area and a second area, the first area being arranged to generate a first amount of heat, the second area being arranged to generate a second amount of heat, the first amount of heat being greater than the second amount of heat, wherein the first fin array is arranged over the first area.

In some aspects, the techniques described herein relate to a system wherein the third plurality of fins forms a second fin array having the first fin density, and wherein the second fin array is arranged over the second area.

In some aspects, the techniques described herein relate to a system wherein the third plurality of fins cooperates with the second plate to form a second fin array having a fourth fin density, and wherein the second fin array is arranged over the second area.

In some aspects, the techniques described herein relate to a system wherein the first plate further includes a third plurality of fins having the first fin density, and the heat source includes a first area and a second area, the first area being arranged to generate a first amount of heat, the second area being arranged to generate a second amount of heat, the first amount of heat being greater than the second amount of heat, wherein the first fin array is arranged to absorb the first amount of heat.

In some aspects, the techniques described herein relate to a system wherein the third plurality of fins forms a second fin array having the first fin density, and wherein the second fin array is arranged to absorb the second amount of heat.

In some aspects, the techniques described herein relate to a system wherein the third plurality of fins cooperates with the second plate to form a second fin array having a fourth fin density, and wherein the second fin array is arranged to absorb the second amount of heat.

In some aspects, the techniques described herein relate to a system wherein the heat source is a computing system.

In some aspects, the techniques described herein relate to an apparatus including: a first plate, the first plate including at least a first plurality of fins integrally formed thereon; and a second plate, the second plate including a surface and at least a second plurality of fins integrally formed thereon, wherein the first plate and the second plate are coupled, and wherein the at least first plurality of fins is bonded to the surface.

In some aspects, the techniques described herein relate to an apparatus wherein the at least first plurality of fins is interleaved with the at least second plurality of fins.

In some aspects, the techniques described herein relate to an apparatus wherein the at least first plurality of fins includes a first fin and a second fin, the first fin and the second fin each having a fin thickness of approximately 0.1 millimeters, wherein the first fin and the second fin are spaced apart by a distance of between approximately 0.2 millimeters and approximately 0.3 millimeters.

In some aspects, the techniques described herein relate to an apparatus wherein the at least second plurality of fins includes a third fin and a fourth fin, the third fin and the fourth fin each having the fin thickness of approximately 0.1 millimeters, wherein the third fin and the fourth fin are spaced apart by a distance of between approximately 0.2 millimeters and approximately 0.3 millimeters, and the third fin is disposed between the first fin and the second fin.

In some aspects, the techniques described herein relate to an apparatus wherein the first plate and the second plate form a cold plate, the apparatus further including: a liquid cooling solution arrangement, the liquid cooling solution arrangement including an inlet and an outlet, the inlet being arranged to provide a liquid to the cold plate, the outlet being arranged to carry the liquid away from the cold plate.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

Although the method and apparatus have been described in accordance with the embodiments shown, one of ordinary skill in the art will readily recognize that there could be variations made without departing from the scope of the embodiments. Accordingly, it is intended that all matter contained in the above description and shown in the accompanying drawings shall be interpreted as illustrative and not in a limiting sense.

What is claimed is:

1. An apparatus comprising:
a first plate, the first plate including a first plurality of fins integrally formed thereon, the first plurality of fins being arranged to have a first fin density; and
a second plate, the second plate including a second plurality of fins integrally formed thereon, the second plurality of fins being arranged to have a second fin density, wherein when the first plate and the second plate are assembled together, the first plurality of fins and the second plurality of fins are interleaved to form a first fin array, the first fin array having a third fin density.

2. The apparatus of claim 1 wherein the first plate further includes a third plurality of fins integrally formed thereon, the third plurality of fins having the first fin density, wherein when the first plate and the second plate are assembled together, the third plurality of fins forms a second fin array, the second fin array having the first fin density.

3. The apparatus of claim 1 wherein the first plate further includes a third plurality of fins integrally formed thereon and the second plate further includes a fourth plurality of fins formed thereon, the third plurality of fins having the first fin density, the fourth plurality of fins having a fourth fin density, wherein when the first plate and the second plate are assembled together, the third plurality of fins and the fourth plurality of fins form a second fin array, the second fin array having a fifth fin density.

4. The apparatus of claim 1 wherein the second plate includes a surface, and wherein when the first plate and the second plate are assembled together, the first plurality of fins is bonded to the surface.

5. The apparatus of claim 4 wherein the first plate is formed from a metal and the second plate is formed from the metal, and wherein the first plurality of fins is bonded to the surface using one selected from a group including diffusion bonding, blazing, and friction bonding.

6. The apparatus of claim 1 wherein when the first plate and the second plate are assembled together, the first plate and the second plate form a cold plate, the apparatus further including:
a liquid cooling solution arrangement, the liquid cooling solution arrangement including an inlet and an outlet, the inlet being arranged to provide a liquid to the cold plate, the outlet being arranged to carry the liquid away from the cold plate.

7. A system comprising:
a heat source; and
a liquid cooling arrangement, the liquid cooling arrangement including a cold plate, a liquid source, a liquid inlet, and a liquid outlet, the liquid cooling arrangement arranged to cool the heat source, wherein the cold plate includes a first plate including a first plurality of fins having a first fin density and a second plate including a second plurality of fins having a second fin density, the first plurality of fins being interleaved with the second plurality of fins to form a first fin array having a third fin density, and wherein the liquid source provides a liquid through the liquid inlet to the cold plate and the liquid outlet carries the liquid away from the cold plate.

8. The system of claim 7 wherein the second plate includes a surface, and wherein the first plurality of fins is bonded to the surface.

9. The system of claim 7 wherein the first plate further includes a third plurality of fins having the first fin density, and the heat source includes a first area and a second area, the first area being arranged to generate a first amount of heat, the second area being arranged to generate a second amount of heat, the first amount of heat being greater than the second amount of heat, wherein the first fin array is arranged over the first area.

10. The system of claim 9 wherein the third plurality of fins forms a second fin array having the first fin density, and wherein the second fin array is arranged over the second area.

11. The system of claim 9 wherein the third plurality of fins cooperates with the second plate to form a second fin array having a fourth fin density, and wherein the second fin array is arranged over the second area.

12. The system of claim 7 wherein the first plate further includes a third plurality of fins having the first fin density, and the heat source includes a first area and a second area, the first area being arranged to generate a first amount of heat, the second area being arranged to generate a second amount of heat, the first amount of heat being greater than the second amount of heat, wherein the first fin array is arranged to absorb the first amount of heat.

13. The system of claim 9 wherein the third plurality of fins forms a second fin array having the first fin density, and wherein the second fin array is arranged to absorb the second amount of heat.

14. The system of claim 9 wherein the third plurality of fins cooperates with the second plate to form a second fin array having a fourth fin density, and wherein the second fin array is arranged to absorb the second amount of heat.

15. The system of claim 9 wherein the heat source is a computing system.

16. An apparatus comprising:
a first plate, the first plate including at least a first plurality of fins integrally formed thereon; and
a second plate, the second plate including a surface and at least a second plurality of fins integrally formed thereon, wherein the first plate and the second plate are coupled, and wherein the at least first plurality of fins is bonded to the surface.

17. The apparatus of claim 16 wherein the at least first plurality of fins is interleaved with the at least second plurality of fins.

18. The apparatus of claim 17 wherein the at least first plurality of fins includes a first fin and a second fin, the first fin and the second fin each having a fin thickness of approximately 0.1 millimeters, wherein the first fin and the second fin are spaced apart by a distance of between approximately 0.2 millimeters and approximately 0.3 millimeters.

19. The apparatus of claim 18 wherein the at least second plurality of fins includes a third fin and a fourth fin, the third fin and the fourth fin each having the fin thickness of approximately 0.1 millimeters, wherein the third fin and the fourth fin are spaced apart by a distance of between approximately 0.2 millimeters and approximately 0.3 millimeters, and the third fin is disposed between the first fin and the second fin.

20. The apparatus of claim 16 wherein the first plate and the second plate form a cold plate, the apparatus further including:
a liquid cooling solution arrangement, the liquid cooling solution arrangement including an inlet and an outlet, the inlet being arranged to provide a liquid to the cold plate, the outlet being arranged to carry the liquid away from the cold plate.
